(19) United States
(12) Patent Application Publication
(10) Pub. No.: US 2026/0089843 A1
(43) Pub. Date: Mar. 26, 2026

(54) ELECTRONIC CONTROL DEVICE

(71) Applicant: DENSO CORPORATION, Kariya-city (JP)

(72) Inventors: Kei SANADA, Kariya-city (JP); Takahiro KURIOKA, Kariya-city (JP)

(21) Appl. No.: 19/321,801

(22) Filed: Sep. 8, 2025

(30) Foreign Application Priority Data
Sep. 26, 2024 (JP) 2024-167434

(51) Int. Cl. H05K 1/14

(52) U.S. Cl. CPC H05K 1/144; H05K 2201/042; H05K 2201/09063

(57) ABSTRACT

An electronic control unit includes a first circuit board, a second circuit, a first connector, a second connector, and a flat cable. The first circuit board and the second circuit board face each other. The first connector is arranged on the first circuit board. The second connector is arranged on the second circuit board. The flat cable electrically connects the first connector and the second connector. At least one circuit element and an auxiliary component are arranged on the second circuit board and positioned directly beneath the flat cable. A height of the auxiliary component is greater than a height of the at least one circuit element. The flat cable is configured to contact the auxiliary component without contacting the at least one circuit element.

### CROSS REFERENCE TO RELATED APPLICATION

The present application claims the benefit of priority from Japanese Patent Application No. 2024-167434 filed on Sep. 26, 2024. The disclosures of all the above applications are incorporated herein.

### TECHNICAL FIELD

The present disclosure relates to an electronic control device.

### BACKGROUND

The performance of functionally integrated ECU (Electronic Control Unit), which consolidates domain control functions such as automated driving, infotainment, and body functions, is improving.

### SUMMARY

An electronic control unit includes a first circuit board, a second circuit, a first connector, a second connector, and a flat cable. The first circuit board and the second circuit board face each other. The first connector is arranged on the first circuit board. The second connector is arranged on the second circuit board. The flat cable electrically connects the first connector and the second connector. The second circuit board has a through-hole. The flat cable passes through the through-hole. The second circuit board has at least one circuit element and an auxiliary component that are arranged on the second circuit board. The auxiliary component does not constitute a circuit. The at least one circuit element and the auxiliary component are positioned directly beneath the flat cable. A height of the auxiliary component is greater than a height of the at least one circuit element. The flat cable is configured to contact the auxiliary component without contacting the at least one circuit element.

### BRIEF DESCRIPTION OF DRAWINGS

The details of one or more embodiments are set forth in the accompanying drawings and the description below. Other features and advantages will be apparent from the description and drawings, and from the claims.

FIG. 1 is a vertical cross-sectional view showing an overall configuration according to a first embodiment.

FIG. 2 is a perspective view of a first printed circuit-board.

FIG. 3 is a perspective view of a second printed circuit-board.

FIG. 4 is a vertical cross-sectional view showing an overall configuration of a comparative example.

FIG. 5 is a vertical cross-sectional view showing an overall configuration according to a second embodiment.

FIG. 6 is a vertical cross-sectional side view showing an overall configuration according to a third embodiment.

### DETAILED DESCRIPTION

The performance of functionally integrated ECU (Electronic Control Unit) that consolidates domain control functions such as automated driving, infotainment, body functions is improving. Accordingly, an amount of data such as image data, transmitted and received between SoCs (System on Chip) that control respective domains, is also becoming enormous. As a result, there may be a demand for a high-bandwidth communication rate between SoCs. For example, it is predicted that by around 2030, a bandwidth of 32 Gbps or more, as represented by PCIe (Peripheral Component Interconnect-Express) Gen5, will be required.

In 32 Gbps NRZ (Non-Return to Zero) communication, a fundamental frequency is 16 GHz. However, when the frequency exceeds several gigahertz, a transmission loss in a circuit-board wiring increases sharply, which becomes a major factor leading to deterioration of communication quality. Since the transmission loss is proportional to a transmission path length, it is becoming difficult to achieve long-distance SoC communication using the circuit-board wiring in a large product such as the functionally integrated ECU. In particular, a FR4 (Flame Retardant Type 4) circuit board, which is commonly used in an automotive ECU, has a significant transmission loss, and a PCIe Gen5 communication can be established only within about 150 mm.

As countermeasures, possible approaches include using low dielectric substrates with lower transmission loss compared to the FR4 circuit board, and using devices such as redrivers or retimers that can recover the transmission loss. However, all of these approaches increase significantly costs. Additionally, in the latter approach, a semiconductor device is placed in a communication path, which also increases a risk of malfunction. Therefore, solutions using a Flexible Flat Cable (hereafter, referred to as FFC), which can provide a low-loss transmission path at a lower cost compared to the low dielectric substrates, the redrivers, and the retimers, are also attracting attention in an automotive field. For example, a first comparative example discloses a configuration in which a first circuit board and a second circuit board facing each other are electrically connected via the FFC.

When the first circuit board and the second circuit board are electrically connected via the FFC and connectors for the FFC are positioned at respective edges of the circuit boards, a wiring on a circuit board between the connector and the SoC becomes longer. As a result, the transmission loss due to the longer circuit-board wiring can cause deterioration of the communication quality. Additionally, when a connector is positioned near the SoC, a clearance between the circuit boards becomes small due to restriction on a thickness of a product unit, making it difficult to connect the FFC to the connectors during assembly.

As a configuration for solving such difficulties, it can be considered a first circuit board and a second circuit board arranged to face each other, a first connector positioned on the first circuit board, a second connector positioned on the second circuit board, and a through hole formed in the second board, where the first connector and the second connector are electrically connected via an FFC passing through the through hole. According to the above-described configuration, since the first connector and the second connector can be positioned near respective SoCs, the transmission loss can be reduced by shortening a circuit-board wiring between the SoCs corresponding the first connector and the second connector, thereby avoiding a risk of deterioration of communication quality. Furthermore, since the FFC can be connected to the first connector via the through hole, a risk of the FFC becoming difficult to be connected to the first connector during assembly can be avoid.

However, in consideration of noise reduction, heat dissipation, and other factors, it may be needed to position an SoC on the first board and an SoC on the second board at a certain distance from each other. Additionally, in order to avoid increasing an overall size of a device, circuit elements may need to be arranged on the second circuit board directly beneath the FFC. As a result, if the circuit elements are arranged directly beneath the FFC, the FFC may come into contact with the circuit elements due to, for example, vehicle vibrations, leading to degradation of the FFC caused by wear. Furthermore, since a clearance between the FFC and the circuit elements decreases, a heat dissipating performance of the circuit elements is reduced, and transmission characteristics of the FFC also degrade due to a heat generated by the circuit elements.

According to the present disclosure, a first connector on a first circuit board and a second connector on a second circuit board are electrically connected in an electronic control device via a flat cable that passes through a through-hole formed in the second circuit board. The electronic control device is capable of securing a high-bandwidth communication rate for internal circuit-board communication and ease of assembling the flat cable, while preventing in advance both degradation of the flat cable and reduction in heat dissipating performance of circuit elements.

According to an aspect of the disclosure, an electronic control unit includes a first circuit board, a second circuit board, a first connector, a second connector, and a flat cable. The first circuit board and the second circuit board face each other. The first connector is arranged on the first circuit board. The second connector is arranged on the second circuit board. The flat cable electrically connects the first connector and the second connector. The second circuit board has a through-hole. The flat cable passes through the through-hole. The second circuit board has at least one circuit element and an auxiliary component that are arranged on the second circuit board. The auxiliary component does not constitute a circuit. The at least one circuit element and the auxiliary component are positioned directly beneath the flat cable. A height of the auxiliary component is greater than a height of the at least one circuit element. The flat cable is configured to contact the auxiliary component without contacting the at least one circuit element.

According to the aspect of the disclosure, the height of the auxiliary component is greater than that of the at least one circuit element, and the auxiliary component is positioned on the second circuit board. The flat cable is capable of contacting the auxiliary component without contacting the at least one circuit element. By adopting the flat cable, the high-bandwidth communication rate for internal circuit-board communication can be ensured. By connecting the flat cable to the first connector via the through-hole, the ease of assembling the flat cable can be ensured. By positioning the auxiliary component so that the flat cable does not come into connect with the at least one circuit element, both degradation of the flat cable and reduction in heat dissipating performance of the at least one circuit element can be prevented in advance. Therefore, the high-bandwidth communication rate for internal circuit-board communication and the ease of assembling the flat cable can be ensured, while preventing in advance both the degradation of the flat cable and the reduction in the heat dissipating performance of the at least one circuit element.

Hereinafter, multiple embodiments applying the present disclosure to, for example, a functionally integrated ECU will be described with reference to the drawings. In the embodiments described below, descriptions of the same portion as those in a preceding embodiment may be omitted. The functionally integrated ECU is, for example, an ECU that consolidates domain control functions such as automated driving, infotainment, and body functions. The integrated domain control functions are not limited to, for example, the automated driving, infotainment, and body functions, described above.

The embodiments of the present disclosure will be described below with reference to the drawings. In the following embodiments, portions that are the same as or equivalent to those described in a preceding embodiment are denoted by the same reference numerals, and a description of the same or equivalent portions may be omitted. When only some of the configuration elements are described in the embodiment, the remaining configuration elements can be referred from those described in the preceding embodiment. The following embodiments may be partially combined with each other even if such a combination is not explicitly described as long as there is no disadvantage with respect to such a combination.

### First Embodiment

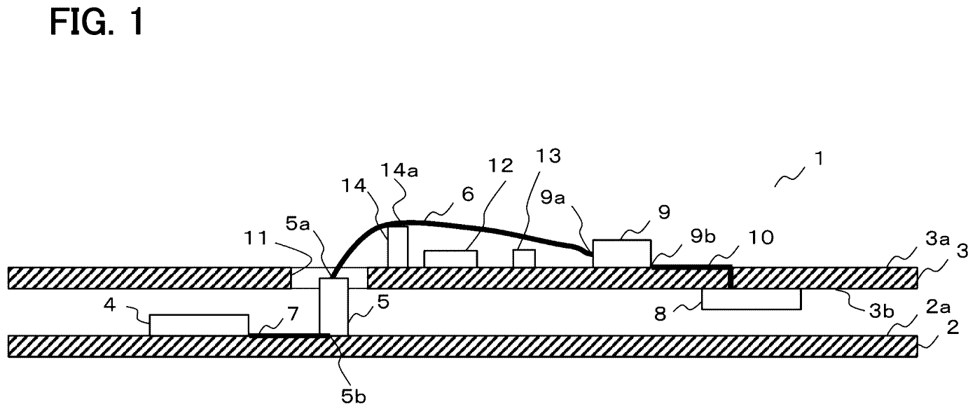

The first embodiment will be described with reference to FIG. 1 to FIG. 4. As shown in FIG. 1, a functionally integrated ECU (hereinafter, referred to as ECU) 1 includes a first printed circuit-board 2 (corresponding to a first circuit board) and a second printed circuit-board 3 (corresponding to a second circuit board). The first printed circuit-board 2 and the second printed circuit-board 3 are arranged to face each other in a vertical direction. The first printed circuit-board 2 is positioned downward to the second printed circuit-board 3, i.e., the second printed circuit-board 3 is positioned upward to the first printed circuit-board 2.

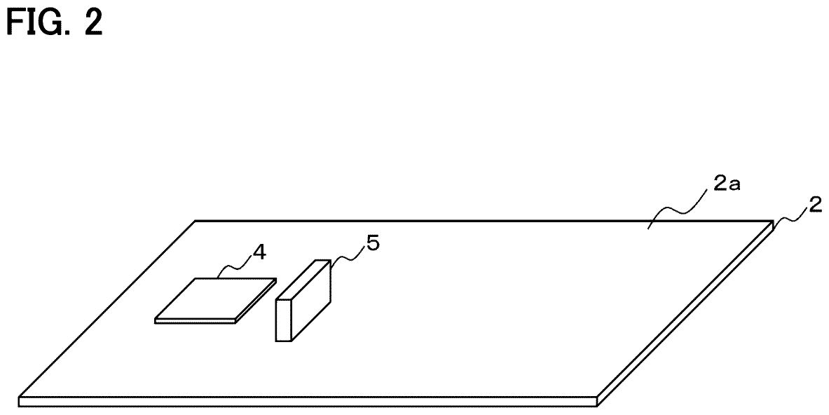

As also shown in FIG. 2, a first SoC (corresponding to a first processor) 4 and a first connector 5 are positioned on an upper surface 2a of the first printed circuit-board 2, i.e., the upper surface 2a facing the second printed circuit-board 3. In FIG. 1, the first connector 5 has a rectangular shape and is positioned on the first printed circuit-board 2. The first connector 5 includes a cable connection portion 5a which serves as a connection portion connected with a FFC 6 (corresponding to a flat cable) and faces upward to the second printed circuit-board 3, and a circuit connection portion 5b which serves as a connection portion connected with the first SoC 4 and faces downward to the first printed circuit-board 2. In other words, the first connector 5 is positioned on the first printed circuit-board 2 such that a longitudinal direction of the first connector 5 is parallel to the vertical direction.

The first SoC 4 and the first connector 5 are electrically connected via a circuit-board wiring 7 formed on the first printed circuit-board 2. In this case, if a length of the circuit-board wiring 7 increases, a resulting transmission loss due to the increased length can cause a decrease in communication quality. Therefore, the length of the circuit-board wiring 7 is, for example, formed as short as possible, taking into consideration factors such as permissible transmission loss and restrictions on an arrangement of circuit elements. Thus, the first connector 5 is positioned in a vicinity of the first SoC 4. The term “vicinity” means a state where at least no other circuit element is interposed between the first connector 5 and the first SoC 4. Additionally, in FIG. 2, the FFC 6 and the circuit-board wiring 7 are omitted.

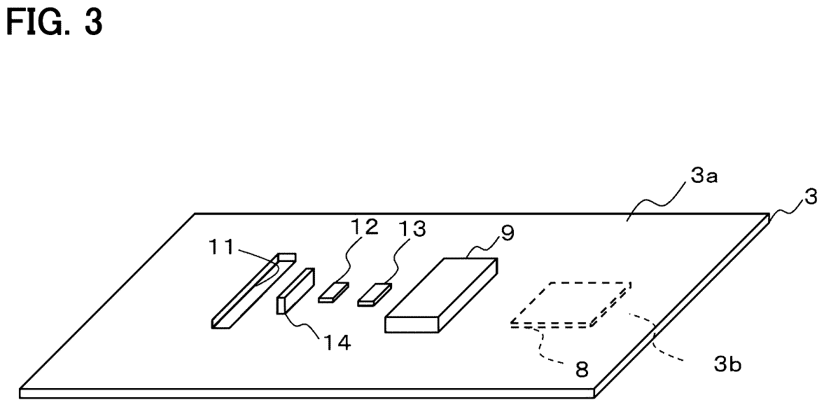

As also shown in FIG. 3, a second SoC (corresponding to a second processor) 8 is positioned on a lower surface 3b of the second printed circuit-board 3, i.e., the lower surface 3b facing the first printed circuit-board 2. A second connector 9 is positioned on an upper surface 3a of the second printed circuit-board 3. In other words, the second connector 9 is positioned on the upper surface 3a of the second printed circuit-board 3, which faces away from the first printed circuit-board 2. In FIG. 1, the second connector 9 has a rectangular shape and is positioned on the second printed circuit-board 3. The second connector 9 includes a cable connection portion 9a which serves as a connection portion connected with the FFC 6 and faces leftward to the first connector 5, and a circuit connection portion 9b which serves as a connection portion connected with the second SoC 8 and faces rightward to the second SoC 8. In other words, the second connector 9 is positioned on the second printed circuit-board 3 such that a longitudinal direction of the second connector 9 is parallel to a horizontal direction.

The second SoC 8 and the second connector 9 are electrically connected via a circuit-board wiring 10 formed on the second printed circuit-board 3. In this case as well, if the length of the circuit-board wiring 10 increases, a resulting transmission loss due to the increased length can cause the decrease in communication quality. Therefore, the length of the circuit-board wiring 10 is, for example, formed as short as possible, taking into consideration the factors such as permissible transmission loss and restrictions on the arrangement of circuit elements. Thus, the second connector 9 is positioned in a vicinity of the second processor 8. The term “vicinity” means a state where at least no other circuit element is interposed between the second connector 9 and the second processor 8. Additionally, in FIG. 3, the FFC 6 and the circuit-board wiring 7 are omitted.

The first SoC 4 and the second SoC 8 are, for example, arranged in different domains. The first SoC 4 is, for example, a processor that performs domain control for automated driving, while the second SoC 8 is, for example, a processor that performs domain control for infotainment. A domain may also be referred to as an application.

A through-hole 11 is formed at a predetermined portion of the second printed circuit-board 3. The cable connection portion 5a, which is the upper end of the first connector 5, is positioned in the through-hole 11 such that an entirety of the cable connection portion 5a can be easily viewed from above the second printed circuit-board 3 through the through-hole 11. One end of the FFC 6 is connected to the cable connection portion 5a of the first connector 5 via the through-hole 11, and the other end of the FFC 6 is connected to the cable connection portion 9a of the second connector 9. As a result, the first connector 5 and the second connector 9 are electrically connected, thereby enabling data communication between the first SoC 4 and the second SoC 8 via the FFC 6 and the circuit-board wirings 7 and 10.

In the process of assembling the FFC 6 to the first connector 5 and the second connector 9, for example, the first connector 5 is positioned on the first printed circuit-board 2, and the second connector 9 is positioned on the second printed circuit-board 3. Thereafter, the other end of the FFC 6 is fitted into the second connector 9, and the one end of the FFC 6 is fitted into the first connector 5. Alternatively, in another process, for example, at first, the other end of the FFC 6 is fitted into the second connector 9. Then, the first connector 5 is positioned on the first printed circuit-board 2, and the second connector 9, into which the other end of the FFC 6 is fitted, is positioned on the second printed circuit-board 3. Thereafter, the one end of the FFC 6 is fitted into the first connector 5.

In the above-described configuration, in consideration of noise reduction, heat dissipation, and other factors, the first SoC 4 on the first printed circuit-board 2 and the second SoC 8 on the second printed circuit-board 3 are arranged at a certain distance from each other. Additionally, as described above, since the first connector 5 is positioned in the vicinity of the first SoC 4 and the second connector 9 is positioned in the vicinity of the second SoC 8, a certain amount of space is secured on the upper surface 3a of the second printed circuit-board 3 between the second connector 9 and the through-hole 11. In this case, in order to avoid an increase in the overall size of the electronic control device, circuit elements 12 and 13 are arranged in the above-described space, i.e., directly beneath the FFC 6. In FIG. 1, although the two circuit elements 12 and 13 are illustrated, the number of circuit elements arranged directly beneath the FFC 6 is not limited to two.

In the present embodiment, an auxiliary component 14 is arranged in the above-described space in the vicinity of the through-hole 11. The auxiliary component 14 is a resin-molded insulator component or an electronic component such as a coil that is not electrically connected to both of the circuit elements 12 and 13, and does not constitute a part of the circuit. The auxiliary component 14 may also be referred to as a dummy component. The auxiliary component 14 has a flat upper end 14a, a height of which is greater than heights of both circuit elements 12 and 13, as well as a height of the second connector 9. In other words, the FFC 6 is supported by being in contact with the upper end 14a of the auxiliary component 14, and is not in contact with both of the circuit elements 12 and 13.

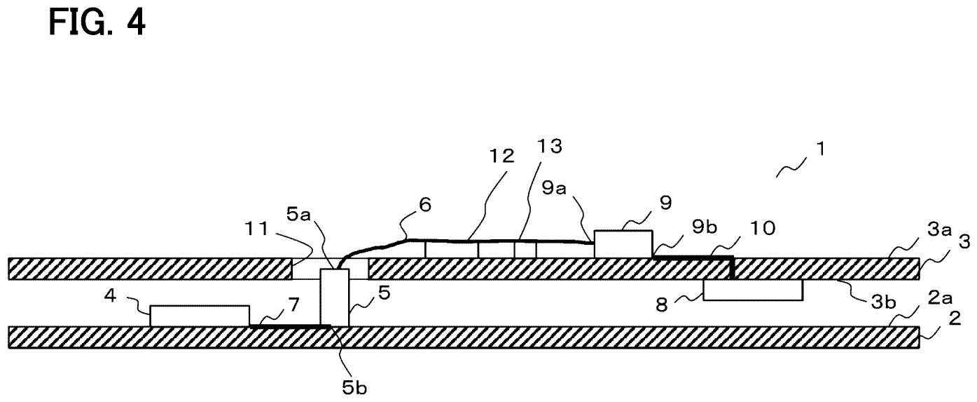

In FIG. 4, a configuration of a comparative example in which the auxiliary component 14 is omitted is shown. In the configuration of the comparative example, since the auxiliary component 14 is omitted, there is a risk of the FFC 6 coming into contact with the circuit elements 12 and 13 due to vehicle vibrations or similar factors, resulting in deterioration of the FFC 6 due to wear. Additionally, the clearance between the FFC 6 and the circuit elements 12 and 13 is reduced, resulting in decrease of a heat dissipating performance of the circuit elements 12 and 13. Furthermore, the transmission characteristics of the FFC 6 may degrade due to a heat generated by the circuit elements 12 and 13.

In contrast, in the configuration of the present embodiment in which the auxiliary component 14 is arranged, the FFC 6 is supported by the auxiliary component 14 and does not come into contact with the circuit elements 12 and 13. As a result, degradation of the FFC 6 can be prevented in advance, and a decrease in the heat dissipating performance of the circuit elements 12 and 13 can also be prevented. Therefore, in the configuration of the present embodiment, since the FFC 6 is capable of realizing a low-loss transmission line, high-bandwidth communication rates between SoCs can be secured. Additionally, since the FFC 6 is connected to the first connector 5 via the through-hole 11, ease of assembling the FFC 6 is ensured. Furthermore, degradation of the FFC 6 and a decrease in the heat dissipating performance of the circuit elements 12 and 13 can be prevented in advance.

The above-described configuration includes the second SoC 8 positioned on the lower surface 3b of the second printed circuit-board 3. However, the second SoC 8 may be positioned on the upper surface 3a of the second printed circuit-board 3. In other words, the second connector 9 may be positioned in the vicinity of the second SoC 8 on the upper surface 3a of the second printed circuit-board 3. Furthermore, the FFC 6 may not be always in contact with the upper end 14a of the auxiliary component 14. The FFC 6 may be brought into contact with the upper end 14a of the auxiliary component 14 at least in a state where the FFC 6 remains out of contact with the circuit elements 12 and 13. In other words, it is sufficient that the FFC 6 is supported by the auxiliary component 14 by being in contact with the upper end 14a of the auxiliary component 14, so that the FFC 6 does not come into contact with the circuit elements 12 and 13.

As described above, according to the first embodiment, the following effects can be obtained. In the ECU 1, the height of the auxiliary component 14, positioned on the second printed circuit-board 3, is greater than the heights of both the circuit elements 12 and 13, and the FFC 6 is positioned to be in contact with the upper end 14a of the auxiliary component 14 so that the FFC 6 does not come into contact with the circuit elements 12 and 13. By adopting the FFC 6, the high-bandwidth communication rates between the SoCs can be secured. By connecting the FFC 6 to the first connector 5 through the through-hole 11, ease of assembling the FFC 6 can be ensured. As a result, it is possible to prevent the degradation of the FFC 6 and the reduction in the heat dissipating performance of the circuit elements 12 and 13 in advance, while securing both the high-bandwidth communication rates between the SoCs and the ease of assembling the FFC 6.

Since the first connector 5 is positioned in the vicinity of the first SoC 4, a transmission loss in the circuit-board wiring 7 can be reduced. Since the second connector 9 is positioned in the vicinity of the second SoC 8, a transmission loss in the circuit-board wiring 10 can be reduced.

Since the auxiliary component 14 is positioned in the vicinity of the through-hole 11, the FFC 6 can be supported at a location as far as possible from the cable connection portion 9a of the second connector 9, thereby appropriately securing the clearance between the FFC 6 and the second printed circuit-board 3. Additionally, a stress applied to the FFC 6 in an area near the second connector 9 can be reduced. If the auxiliary component 14 is positioned in the vicinity of the second connector 9, there may be a risk that the FFC 6 has to be excessively bent. This risk may result in the inability to properly secure the clearance between the FFC 6 and the second printed circuit-board 3, or in an increase in the stress applied to the FFC 6 near the second connector 9. However, by arranging the auxiliary component 14 near the through-hole 11, such risk can be avoided in advance.

Since the second connector 9 is positioned on the upper surface 3a of the second printed circuit-board 3, it is possible to improve workability when the FFC 6 is assembled to the second connector 9 in a state where the second connector 9 is mounted on the second printed circuit-board 3. Additionally, the clearance between the first printed circuit-board 2 and the second printed circuit-board 3 can be reduced, thereby enabling miniaturization of the entire device.

Since the dimension of the auxiliary component 14 in the height direction is made greater compared to the second connector 9, the clearance between the FFC 6 and the second printed circuit-board 3 can be appropriately secured.

### Second Embodiment

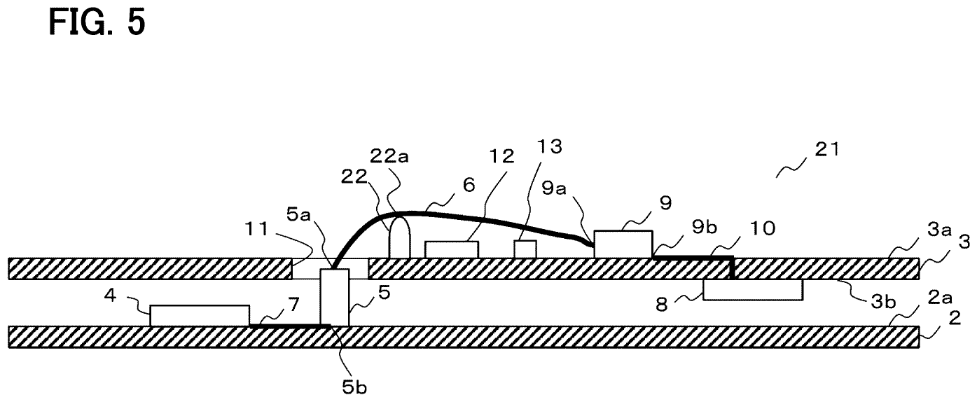

A second embodiment will be described with reference to FIG. 5. The second embodiment is different from the first embodiment in a shape of an auxiliary component. In an ECU 21, an auxiliary component 22 is positioned directly beneath an FFC 6 and in a vicinity of a through-hole 11. The only difference between the auxiliary component 22 and the auxiliary component 14 of the first embodiment is that an upper end 22a of the auxiliary component 22 is arc-shaped. A height of the auxiliary component 22 is greater than heights of both circuit elements 12 and 13 and a height of the second connector 9. In other words, the FFC 6 is supported by the auxiliary component 22 by being in contact with the upper end 22a of the auxiliary component 22 while the FFC 6 does not come into contact with any of the circuit elements 12 and 13.

According to the above-described second embodiment, the following effects can be obtained. In the ECU 21, the height of the auxiliary component 22, positioned on a second printed circuit-board 3, is greater than the heights of the circuit elements 12 and 13, and the FFC 6 is made in contact with the upper end 22a of the auxiliary component 22 so that the FFC 6 does not come into contact with both of the circuit elements 12 and 13. The same effects as those of the first embodiment can be obtained. Additionally, it is possible to prevent degradation of the FFC 6 in advance and a reduction in the heat dissipating performance of the circuit elements 12 and 13, while securing high-bandwidth communication rates between SoCs and ensuring ease of assembling the FFC 6.

Since the upper end 22a of the auxiliary component 22 is formed in an arc shape, it is possible not only to appropriately reduce the wear of the FFC 6 at a portion of the FFC 6 being in contact with the auxiliary component 22, but also to properly support the FFC 6 by increasing the contact area.

### Third Embodiment

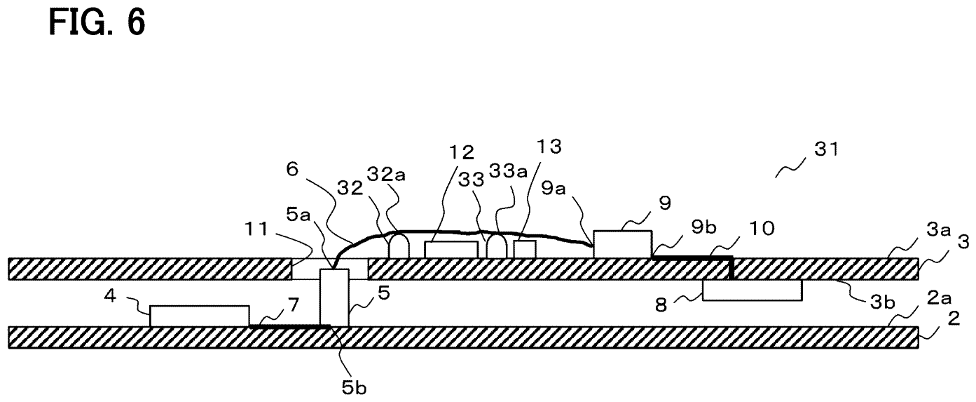

A third embodiment will be described with reference to FIG. 6. The third embodiment differs from the second embodiment in the number of auxiliary components. In an ECU 31, an auxiliary component 32 is positioned immediately directly beneath an FFC 6 and in a vicinity of a through-hole 11, and an auxiliary component 33 is positioned between a circuit element 12 and a circuit element 13. The auxiliary component 32 has an upper end 32a with an arc shape similar to the auxiliary component 22 described in the second embodiment, and a height of the auxiliary component 32 is greater than a height of the circuit element 12 positioned in the vicinity of the auxiliary component 32 and a height of the second connector 9. The auxiliary component 33 has an upper end 33a with an arc shape similar to the auxiliary component 22 described in the second embodiment, and a height of the auxiliary component 33 is greater than heights of the circuit elements 12 and 13 positioned in the vicinity of the auxiliary component 33 and a height of the second connector 9.

According to the above-described third embodiment, the following effects can be obtained. In the ECU 31, the heights of the auxiliary components 22 and 23, positioned on the second printed circuit-board 3, are greater than the heights of the circuit elements 12 and 13, and the FFC 6 is made in contact with the upper end 32a of the auxiliary component 32 and the upper end 33a of the auxiliary component 33 so that the FFC 6 does not come into contact with any of the circuit elements 12 and 13. The same effects as those of the first embodiment can be obtained. Additionally, it is possible to prevent degradation of the FFC 6 in advance and a reduction in the heat dissipating performance of the circuit elements 12 and 13, while securing high-bandwidth communication rates between SoCs and ensuring ease of assembling the FFC 6.

Additionally, by arranging the multiple auxiliary components 32 and 33 and setting each height of them to the minimum dimension for preventing the FFC 6 from coming into contact with adjacent circuit elements, it is possible to prevent an upward curving of the FFC 6 due to an arrangement of the auxiliary components 32 and 33, thereby reducing an overall height of a device. Furthermore, since the upper ends 32a and 33a of the auxiliary components 32 and 33 are formed in arc shape, it is possible not only to reduce the wear of the FFC 6 at portions of the FFC 6 being in contact with the auxiliary components 32 and 33, but also to properly support the FFC 6 by increasing the contact area.

### Other Embodiments

Although the present disclosure has been made in accordance with the embodiments, it is understood that the present disclosure is not limited to such embodiments and structures. The present disclosure also includes various modifications and equivalents. Additionally, various combinations and configurations, as well as other combinations and configurations including more, less, or only a single element, are within the scope and spirit of the present disclosure.

The present disclosure is not limited to a configuration applied to a functionally integrated ECU. For example, the present disclosure may include a configuration applied to an ECU that performs a single function, such as a meter ECU controlling a meter, or an engine ECU controlling an engine.

Although the configuration has been exemplified in which the first printed circuit-board 2 and the second printed circuit-board 3 are arranged to face each other in the vertical direction, the present disclosure may also be applied to a configuration in which a first printed circuit-board 2 and a second printed circuit-board 3 are arranged to face each other in the horizontal direction. Additionally, the first printed circuit-board 2 and the second printed circuit-board 3 may also be arranged upside down.

Multiple connectors corresponding to the first connector 5 may be positioned on the first printed circuit-board 2, and multiple connectors corresponding to the second connector 9 may be positioned on the second printed circuit-board 3. Multiple relationships corresponding to the above-described relationship between an FFC 6 and an auxiliary component 14 may be provided accordingly.

In a configuration including three or more facing printed circuit-boards, multiple relationships corresponding to the relationship between the first printed circuit-board 2 and the second printed circuit-board 3 may also be provided.

While the present disclosure has been described with reference to embodiments thereof, it is to be understood that the disclosure is not limited to the embodiments and constructions. To the contrary, the present disclosure is intended to cover various modification and equivalent arrangements. In addition, while the various elements are shown in various combinations and configurations, which are exemplary, other combinations and configurations, including more, less or only a single element, are also within the spirit and scope of the present disclosure.

What is claimed is:

1. An electronic control unit, comprising:
a first circuit board and a second circuit board facing each other;
a first connector arranged on the first circuit board;
a second connector arranged on the second circuit board; and
a flat cable electrically connecting the first connector and the second connector, wherein
the second circuit board has a through-hole,
the flat cable passes through the through-hole,
the second circuit board has at least one circuit element and an auxiliary component that are arranged on the second circuit board,
the auxiliary component does not constitute a circuit,
the at least one circuit element and the auxiliary component are positioned directly beneath the flat cable,
a height of the auxiliary component is greater than a height of the at least one circuit element, and
the flat cable is configured to contact the auxiliary component without contacting the at least one circuit element.

2. The electronic control unit according to claim 1, wherein
the first circuit board has a first processor arranged on the first circuit board, and
the first connector is positioned in a vicinity of the first processor and is electrically connected to the first processor.

3. The electronic control unit according to claim 1, wherein
the second circuit board has a second processor arranged on the second circuit board, and
the second connector is positioned in a vicinity of the second processor and is electrically connected to the second processor.

4. The electronic control unit according to claim 1, wherein
the auxiliary component is positioned in a vicinity of the through-hole.

5. The electronic control unit according to claim 1, wherein
the second connector is arranged on a surface of the second circuit board that faces away from the first circuit board.

6. The electronic control unit according to claim 1, wherein
the height of the auxiliary component is greater than a height of the second connector.

7. The electronic control unit according to claim 1, wherein
the auxiliary component has an arc-shaped surface in contact with the flat cable.

8. The electronic control unit according to claim 1, wherein
the auxiliary component is one of auxiliary components positioned in a vicinity of the at least one circuit element, and
each height of the auxiliary components is greater than the height of the at least one circuit element.
